(19) United States
(12) Patent Application Publication
(10) Pub. No.: US 2019/0301019 A1
(43) Pub. Date: Oct. 3, 2019

(54) BORON-BASED FILM FORMING METHOD AND APPARATUS

(71) Applicant: TOKYO ELECTRON LIMITED, Tokyo (JP)

(72) Inventors: Yoshimasa WATANABE, Yamanashi (JP); Masahiro OKA, Yamanashi (JP); Jinwang LI, Yamanashi (JP); Yuuki YAMAMOTO, Yamanashi (JP); Hirokazu UEDA, Yamanashi (JP)

(21) Appl. No.: 16/363,531

(22) Filed: Mar. 25, 2019

(30) Foreign Application Priority Data
Mar. 28, 2018 (JP) 2018-061664

(51) Int. Cl. C23C 16/505; C23C 16/52; C23C 16/22

(52) U.S. Cl. CPC C23C 16/505; H01J 37/32174; C23C 16/22; C23C 16/52

(57) ABSTRACT

There is provided a boron-based film forming method for forming a boron-based film mainly containing boron on a substrate. The method includes steps of loading a substrate into a chamber of a film forming apparatus for forming the boron-based film by plasma CVD using capacitively-coupled plasma, supplying a processing gas containing a boron-containing gas into the chamber, applying a high frequency power for generating the capacitively-coupled plasma and forming the boron-based film on the substrate by generating a plasma of the processing gas by the high frequency power. A film stress of the boron-based film is adjusted by the high frequency power in the applying step.

### CROSS-REFERENCE TO RELATED APPLICATION

This application claims priority to Japanese Patent Application No. 2018-061664 filed on Mar. 28, 2018, the entire contents of which are incorporated herein by reference.

### TECHNICAL FIELD

The present disclosure relates to a boron-based film forming method and apparatus.

### BACKGROUND

Recently, miniaturization of semiconductor devices has progressed along with developments of semiconductor manufacturing technologies, thereby allowing semiconductor devices to have a size equal to or less than 14 nm or a size equal to or less than 10 nm. Further, a technique for three-dimensionally constructing semiconductor elements has been developed for integration of newly developed semiconductor devices. Therefore, the number of thin films laminated on a semiconductor wafer has increased. For example, in a 3D NAND flash memory, there is a demand to perform microprocessing using dry etching on a laminated film having a thickness of 1 μm or more that includes a silicon oxide (SiO₂) film, a silicon nitride (SiN) film, or the like.

An amorphous silicon film or an amorphous carbon film has been conventionally used as a hard mask for performing microprocessing. However, such a film has low etching resistance. Therefore, in the case of using such a film as the hard mask, a large film thickness is required and, thus, it is necessary to form a thick film of 1 μm or more.

As for next-generation hard mask material, a metal film such as a tungsten film or the like, which has higher etching resistance than that of the amorphous silicon film or the amorphous carbon film, has been examined. However, using such a metal film having high etching resistance causes peeling or metal contamination after dry etching and, thus, it is difficult to use the metal film such as the tungsten film or the like as the next-generation hard mask material.

Therefore, a boron-based film has been examined as a new hard mask material having higher dry etching resistance compared to the amorphous silicon film or the amorphous carbon film and having high selectivity with respect to an SiO₂ film or the like. Japanese Patent Application Publication No. 2013-533376 discloses that a boron-based film formed by CVD can be used as a hard mask.

### SUMMARY

In accordance with an embodiment of the present disclosure, there is provided a boron-based film forming method for forming a boron-based film mainly containing boron on a substrate, including: loading a substrate into a chamber of a film forming apparatus for forming the boron-based film by plasma CVD using capacitively-coupled plasma; supplying a processing gas containing a boron-containing gas into the chamber; applying a high frequency power for generating the capacitively-coupled plasma; and forming the boron-based film on the substrate by generating a plasma of the processing gas by the high frequency power. Further, a film stress of the boron-based film is adjusted by the high frequency power in the applying.

### BRIEF DESCRIPTION OF THE DRAWINGS

The objects and features of the present disclosure will become apparent from the following description of embodiments, given in conjunction with the accompanying drawings, in which:

FIG. 1 is a cross-sectional view showing an example of a film forming apparatus for performing a boron-based film forming method according to an embodiment;

FIG. 2 is a flowchart for explaining the boron-based film forming method according to the embodiment;

FIG. 3 shows dry etching characteristics of a boron film formed by capacitively-coupled plasma CVD by comparing the boron film with an amorphous carbon film or an amorphous silicon film;

FIG. 4 is a graph showing a relationship between RF power and film stress in the case of forming a boron film while varying the RF power by the film forming apparatus configured as a capacitively-coupled plasma CVD apparatus shown in FIG. 1;

FIG. 5 is a graph showing the relationship shown in FIG. 4 when the RF power on the horizontal axis of FIG. 4 is converted to logarithmic scale;

FIG. 6 shows a result of FT-IR measurement of a boron film that is formed while varying RF power for plasma generation;

FIG. 7 is a graph showing a relationship between film thickness of a boron film and surface roughness RMS of the boron film in the case of setting RF power for plasma generation to 1000 W and 100 W;

FIG. 8 is a graph showing a relationship between RF power for plasma generation, film stress and film forming rate;

FIG. 9 is a graph showing a relationship between pressure and film stress in the case of setting RF power for plasma generation to 100 W, 500 W, and 1000 W;

FIG. 10 is a graph showing the relationship shown in FIG. 9 to which a plot of a high-pressure side at 100 W is added while the pressure on the horizontal axis of FIG. 9 is converted to logarithmic scale;

FIG. 11 is a graph showing a relationship between an Ar gas dilution ratio (%) and film stress in the case of setting the RF power for plasma generation to 100 W, 500 W, and 1000 W;

FIG. 12 shows a result of FT-IR measurement of a boron film in the case of varying pressure;

FIG. 13 shows a result of FT-IR measurement of a boron film in the case of varying the Ar gas dilution ratio;

FIG. 14 is a graph showing a relationship between a high-frequency power for bias and film stress;

FIG. 15 shows a result of FT-IR measurement of a boron film in the case of varying the high-frequency power for bias;

FIG. 16 is a cross-sectional view showing another example of the film forming apparatus for performing the boron-based film forming method.

### DETAILED DESCRIPTION

Hereinafter, embodiments will be described in detail with reference to the accompanying drawings.

<Circumstances>

First, the circumstances that have led to the boron-film forming method of the present disclosure will be described. A boron-based film is regarded as the best candidate for a hard mask to be used in a patterning process using dry etching. Conventionally, a boron-based film is formed by CVD. Even among boron-based films, it is known that a boron film containing boron alone has excellent characteristics as a hard mask.

Along with miniaturization and multilayer structures of semiconductor devices, diversification and film thickening have progressed for hard mask materials. Further, various film characteristics other than characteristics in dry etching are required. For example, the film stress of a film made of the hard mask material becomes significant in view of the adhesivity of the film, the warpage of a substrate (i.e., wafer), or the like. Further, along with the miniaturization of semiconductor devices, flatness (root mean square (RMS) roughness) of the film itself also becomes significant, and a film having a surface roughness (RMS) of 1 nm or less is required for a hard mask.

However, the boron-based film formed by CVD does not have satisfactory film stress or flatness, and there is a demand to have a boron-based film having satisfactory film stress or flatness. Japanese Patent Application Publication No. 2013-533376 discloses that a boron-based film formed by CVD can be used as a hard mask. However, there is no disclosure of a film forming method capable of obtaining a film stress and a surface flatness suitable for hard mask material.

As a result of examination by the present inventors, it was found that the film stress of the boron-based film could be adjusted by adjusting a high frequency power while using a capacitively coupled plasma CVD apparatus. It was also found that, by forming the boron-based film at the high frequency power of 500 W or less, which is lower than that used in a conventional capacitively coupled plasma CVD apparatus, it was possible to reduce the film stress and improve the surface flatness so that a boron-based film suitable for the hard mask was obtained.

In the present disclosure, a target boron-based film to be formed is a film mainly containing boron, which contains boron of, e.g., 50 at. % or more. The boron-based film may be a boron film containing boron and inevitable impurities or may be a boron film containing boron and other elements such as nitrogen (N), carbon (C), silicon (Si), and the like, which have been intentionally added to boron. However, in view of a high etching resistance, it is preferable to use a boron film containing no other additives. In the following embodiments, an example in which a boron film containing no additives is used to describe the boron-based film.

<Film Forming Apparatus>

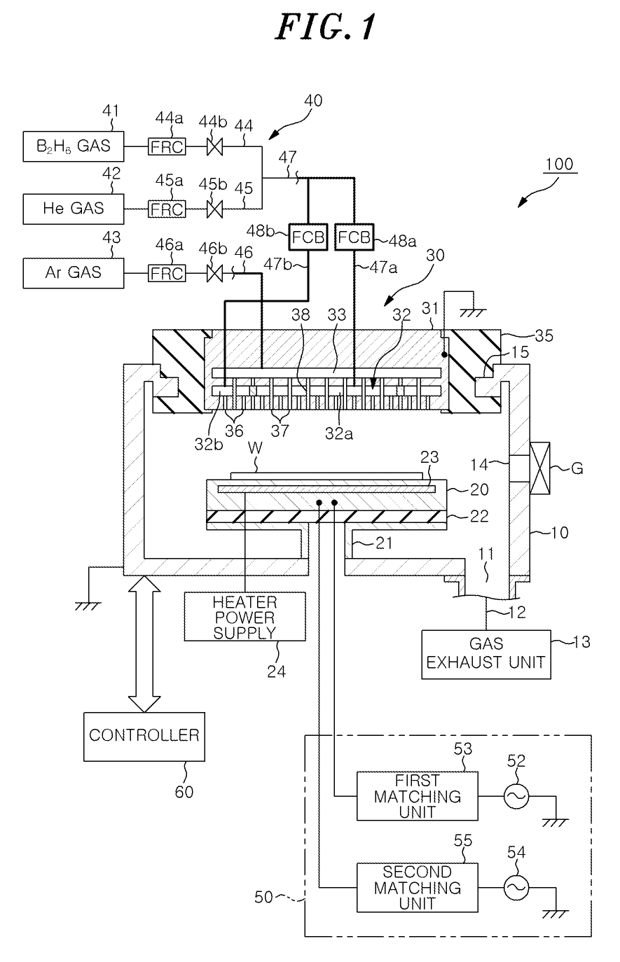

FIG. 1 is a cross-sectional view showing an example of a film forming apparatus for performing a boron-based film forming method according to an embodiment. A film forming apparatus 100 in this example is configured as a capacitively coupled plasma CVD apparatus for forming a boron film.

The film forming apparatus 100 is configured as a parallel plate type (capacitively coupled type) plasma etching apparatus in which a mounting table (stage) 20 and a gas shower head 30 are disposed to face each other in a chamber 10. The mounting table 20 serves as a lower electrode and the gas shower head 30 serves as an upper electrode. The film forming apparatus 100 further includes a gas supply mechanism 40, a high frequency power supply device 50 and a controller 60.

The chamber 10 has a substantially cylindrical shape. Further, the chamber 10 is made of, e.g., aluminum having an anodically oxidized surface and is electrically grounded. A gas exhaust port 11 is formed at the bottom surface of the chamber 10, and a gas exhaust line 12 is connected to the gas exhaust port 11. A gas exhaust unit 13 including a vacuum pump, a pressure control valve, or the like is connected to the gas exhaust line 12. The gas exhaust unit 13 exhausts the chamber 10 and controls the pressure in the chamber 10 to a predetermined level (vacuum level). A wafer loading/unloading port 14 for loading and unloading a semiconductor wafer W (hereinafter, simply referred to as “wafer W”) as a target substrate is provided at a sidewall of the chamber 10. The wafer loading/unloading port 14 is opened and closed by a gate valve G. In a state where the gate valve G is opened, the wafer W is loaded into and unloaded from the chamber 10.

The mounting table 20 is arranged at a central portion of a bottom portion of the chamber 10 to mount the wafer W thereon. The mounting table 20 is made of a metal. The mounting table 20 is supported by a metallic supporting member 21 provided at the bottom surface of the chamber 10 via an insulating member 22. A resistance heater 23 is embedded in the mounting table 20. The resistance heater 23 generates heat by power supplied from a heater power supply 24. Accordingly, the wafer W is heated to a predetermined temperature through the mounting table 20.

Wafer lift pins (not shown) are provided at the mounting table 20 to protrude beyond and retract below a top surface of an electrostatic chuck. The wafer W is transferred in a state where the wafer lift pins protrude beyond the top surface of the electrostatic chuck.

The gas shower head 30 has a disk shape and is fitted into an annular lid 15 provided at an upper portion of the chamber 10 through a shield ring 35 made of an insulator. The gas shower head 30 forms a ceiling portion of the chamber 10. The gas shower head 30 may be electrically grounded as shown in FIG. 1, or a predetermined DC voltage may be applied to the gas shower head 30 from a variable DC power supply connected thereto.

The gas shower head 30 has a main body 31. In the main body 31, a disk-shaped main gas diffusion space 32 and a disk-shaped auxiliary gas diffusion space 33, which are slightly greater than the wafer W in size, are provided in two stages. The main gas diffusion space 32 is divided into a first gas diffusion space 32a provided at a central portion thereof and a second annular gas diffusion space 32b provided at an edge portion thereof.

A plurality of first gas injection holes 36 is formed at the bottom portion of the main body 31 to extend from the first gas diffusion space 32a and the second gas diffusion space 32b of the main gas diffusion space 32 to face the inside of the chamber 10. A plurality of second gas injection holes 37 is formed at the bottom portion of the main body 31 to extend from the auxiliary gas diffusion space 33 to face the inside of the chamber 10. The first gas injection holes 36 and the second gas injection holes 37 are alternately formed. The second gas injection holes 37 reach the bottom portion of the main body 31 from the auxiliary gas diffusion space 32 while penetrating through lines 38 in the first gas diffusion space 31a and the second gas diffusion space 31b of the main gas diffusion space 31.

The gas supply mechanism 40 is configured to supply a processing gas containing a boron-containing gas. The boron-containing gas may be diborane (B₂H₆) gas, boron trichloride (BCl₃) gas, alkylborane gas, decaborane gas, or the like. The alkylborane gas may be trimethylborane (B(CH₃)₃) gas, triethylborane (B(C₂H₅)₃) gas, a gas expressed by B(R1)(R2)(R3), B(R1)(R2)H, or B(R1)H2 (R1, R2, R3 being alkyl groups), or the like. Among them, B₂H₆ gas can be suitably used.

The processing gas contains a rare gas for plasma excitation. Further, the processing gas may contain H₂ gas or the like. As for the rare gas, He gas, Ar gas or the like is used. Hereinafter, as an example, there will be described a case of using a processing gas containing B₂H₆ gas as the boron-containing gas and Ar gas and He gas as the rare gas.

The gas supply mechanism 40 includes a B₂H₆ gas supply source 41, an He gas supply source 42, an Ar gas supply source 43, and pipes 44, 45, and 46 respectively extending from these gas supply sources. A flow rate controller (FRC) 44a such as a mass flow controller and an opening/closing valve 44b are provided at the pipe 44. A flow rate controller (FRC) 45a and an opening/closing valve 45b are provided at the pipe 45. A flow rate controller (FRC) 46a and an opening/closing valve 46b are provided at the pipe 46. The pipe 44 extending from the B₂H₆ gas supply source 41 and the pipe 45 extending from the He gas supply source 42 join with the pipe 47. The pipe 47 branches into a first distribution pipe 47a and a second distribution pipe 47b. Flow control valves (FCB) 48a and 48b are provided in the first distribution pipe 47a and the second distribution pipe 47b, respectively. The first distribution pipe 47a and the second distribution pipe 47b are respectively connected to the first gas diffusion space 32a and the second gas diffusion space 32b of the main gas diffusion space 32. Accordingly, B₂H₆ gas and He gas are distributed to the first gas diffusion space 32a and the second gas diffusion space 32b at a predetermined distribution ratio, and the amounts of the B₂H₆ gas and the He gas can be changed at the central portion and the peripheral portion of the wafer W. The pipe 46 extending from the Ar gas supply source 43 is connected to the auxiliary gas diffusion space 33, and Ar gas is uniformly injected into the entire surface of the wafer W. By supplying the He gas and the Ar gas through separate gas supply sources, the flow rate ratio between the He gas and the Ar gas can be adjusted.

The high frequency power supply device 50 is configured to supply dual-frequency synthesized high frequency power to the mounting table 20. The high frequency power supply device 50 includes a first high frequency power supply 52 for supplying a first high frequency power at a first frequency for plasma generation, and a second high frequency power supply 54 for supplying a second high frequency power at a second frequency lower than the first frequency for bias voltage application. The first high frequency power supply 52 is electrically connected to the mounting table 20 through a first matching unit 53. The second high frequency power supply 54 is electrically connected to the mounting table 20 through a second matching unit 55. The first high frequency power supply 52 applies a first high frequency power of, e.g., 40 MHz, to the mounting table 20. The second high frequency power supply 54 applies a second high frequency power of, e.g., 3 MHz, to the mounting table 20. The first high frequency power may be applied to the gas shower head 30.

The first matching unit 53 is configured to match a load impedance with an internal (or output) impedance of the first high frequency power supply 52. Specifically, the first matching unit 53 functions such that the load impedance and the output impedance of the first high frequency power supply 52 match when a plasma is generated in the chamber 10. The second matching unit 55 is configured to match the load impedance with an internal (or output) impedance of the second high frequency power supply 54. Specifically, the second matching unit 55 functions such that the load impedance and the internal impedance of the second high frequency power supply 54 match when a plasma is generated in the chamber 10.

The high frequency power from the first high frequency power supply 52 may be modulated in a pulse shape and applied. The period of the pulse is preferably about 5 to 40 kHz.

The controller 60 is configured to control the respective components of the film forming apparatus 100. For example, the controller 60 controls the valves, the flow rate controllers, the first high frequency power supply 52, the second high frequency power supply 54, the gas exhaust unit 13, the power supplied from the heater power supply 24 to the heater 23, and the like. The controller 60 includes a main control unit having a CPU, an input device, an output device, a display device, and a storage device. The storage device includes a storage medium in which a program, i.e., a processing recipe, for controlling processing performed in the film forming apparatus 100 is stored. The main control unit reads out a predetermined processing recipe stored in the storage medium and controls the film forming apparatus 100 to perform predetermined processing based on the processing recipe.

<Boron-Based Film Forming Method>

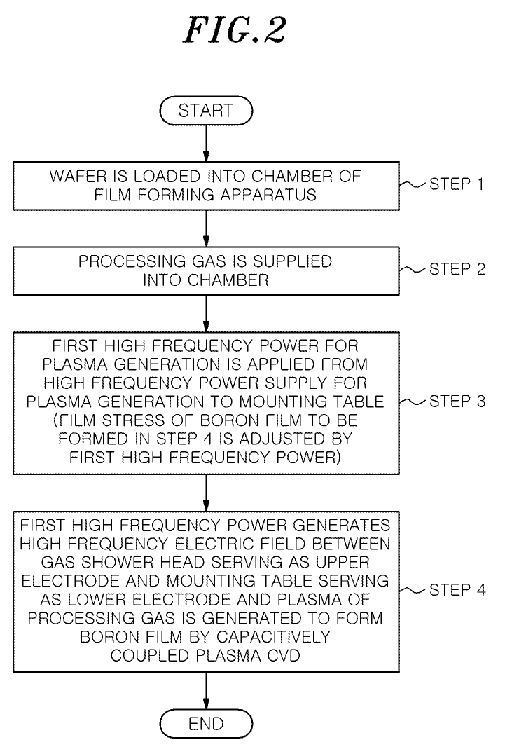

Hereinafter, a film forming method of a boron film as a boron-based film performed by the film forming apparatus 100 configured as described above will be described with reference to the flowchart of FIG. 2.

First, the gate valve G is opened and the wafer W is loaded into the chamber 10 of the film forming apparatus 100 (step 1). Then, the wafer W is mounted on the mounting table 20 and the gate valve G is closed.

The temperature of the mounting table 20 is set to 500° C. or less, and preferably 60 to 500° C., e.g., 300° C. After the chamber 10 is evacuated, a processing gas is supplied into the chamber 10 (step 2). In order to supply the processing gas, first, a cycle purge is performed by flowing Ar gas and He gas into the chamber 10. Then, B₂H₆ gas is supplied. During the cycle purge using the Ar gas and the He gas, the pressure in the chamber 10 is set to, e.g., about 400 mTorr to stabilize the temperature of the wafer. The supplying of the B₂H₆ gas is performed as follows. B₂H₆ gas diluted with He gas is supplied with a flow rate of B₂H₆ gas (net amount) in a range of 5 to 50 sccm, e.g., 30 sccm. Ar gas and/or He gas is supplied at a flow rate in a range of 100 to 1000 sccm, e.g., 400 sccm (total amount), into the chamber 10. Accordingly, the pressure in the chamber 10 is controlled to be in a range from 100 mTorr to 10 Torr (i.e., a range from 13.3 Pa to 1333.3 Pa).

Then, the first high frequency power for plasma generation is applied from the first high frequency power supply 52 to the mounting table 20 (step 3). In this step, the film stress of a boron film that is a boron-based film to be formed in step 4 is adjusted by the high frequency power, as will be described later. The first high frequency power generates a high frequency electric field between the gas shower head 30 serving as the upper electrode and the mounting table 20 serving as the lower electrode; a plasma of the processing gas is generated; and the boron film is formed by capacitively coupled plasma CVD (step 4). The boron film formed at this time is generally amorphous boron (a-B). The film formation time of the boron film is appropriately set depending on the film thickness.

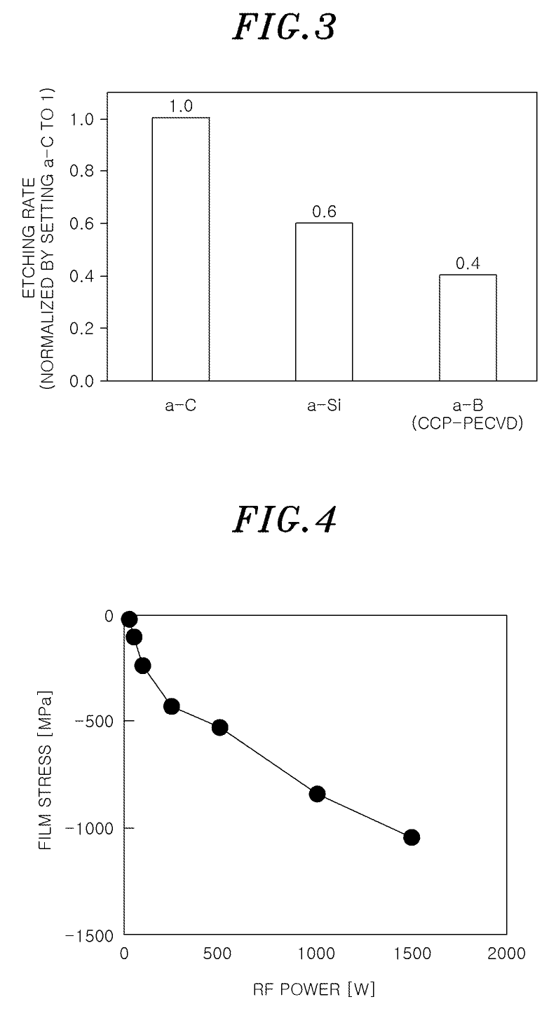

The boron film (amorphous boron a-B) formed by plasma CVD has a high selectivity against an SiO₂ film or an SiN film during dry etching. Therefore, as shown in FIG. 3, when etching is performed by a gas containing a CF-based gas with at least one of Ar gas, O₂ gas, N₂ gas, H₂ gas, or the like added, the etching resistance of the boron film becomes higher than that of an amorphous carbon film (a-C) or an amorphous silicon film (a-Si), which have been conventionally used as hard mask material. Therefore, by employing the boron film as a hard mask or the like, the manufacturing of semiconductor devices becomes easier.

The hard mask material film requires low film stress in view of adhesivity of the film and warpage of the wafer serving as a substrate. Further, along with the miniaturization of semiconductor devices, flatness of the film itself (surface roughness; e.g., root mean square roughness (RMS)) became important.

In the case of forming a boron-based film such as a boron film by CVD, the film stress can be adjusted by adjusting the high frequency power (RF power) for plasma generation and by using a capacitively coupled plasma CVD apparatus employed in the present embodiment. This will be described in detail as follows.

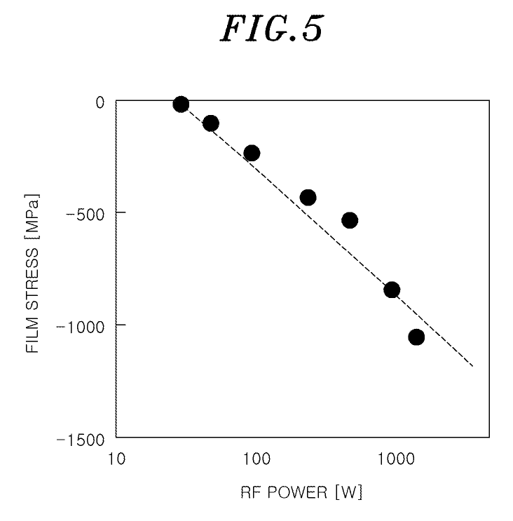

FIG. 4 is a graph showing a relationship between the RF power and the film stress in the case of forming a boron film while varying the RF power by the film forming apparatus 100 configured as the capacitively-coupled plasma CVD apparatus shown in FIG. 1. FIG. 5 is a graph showing the relationship shown in FIG. 4 when the RF power on the horizontal axis of FIG. 4 is converted to logarithmic scale.

Other processing conditions are as follows:

temperature: 300° C.

pressure: 500 mTorr (66.7 Pa)

B₂H₆ gas flow rate (B₂H₆ concentration: 15 vol % in He gas): 200 sccm (B₂H₆ gas (net amount): 30 sccm, He gas: 170 sccm)

Ar gas flow rate: 100 sccm

He gas flow rate: 100 sccm

gap between electrodes: 20 mm.

The negative direction of the stress is a compressive direction.

As shown in FIGS. 4 and 5, the film stress can be adjusted by the RF power for plasma generation. In the film formation using the capacitively coupled plasma CVD, the RF power of 1000 W or more is generally used for plasma generation. However, as shown in FIGS. 4 and 5, when the RF power is 1000 W or more, the film stress becomes 1 GPa or more, which is a large compressive stress. In contrast, the film stress is reduced by lowering the RF power. Specifically, the film stress of 500 MPa or less, which is suitable for the hard mask, can be obtained when the RF power of 500 W or less is used. Further, the film stress of 300 MPa or less that is much more suitable for the hard mask can be obtained when the RF power of 100 W or less is used. Conventionally, generating capacitively-coupled plasma at such a low power while forming a film having such a small stress was not expected.

The following descriptions will explain an examination result of the above-described mechanism in which the film stress of the boron film, which is a boron-based film, is adjusted by the RF power for capacitively-coupled plasma generation and the film stress is reduced as the RF power is lowered.

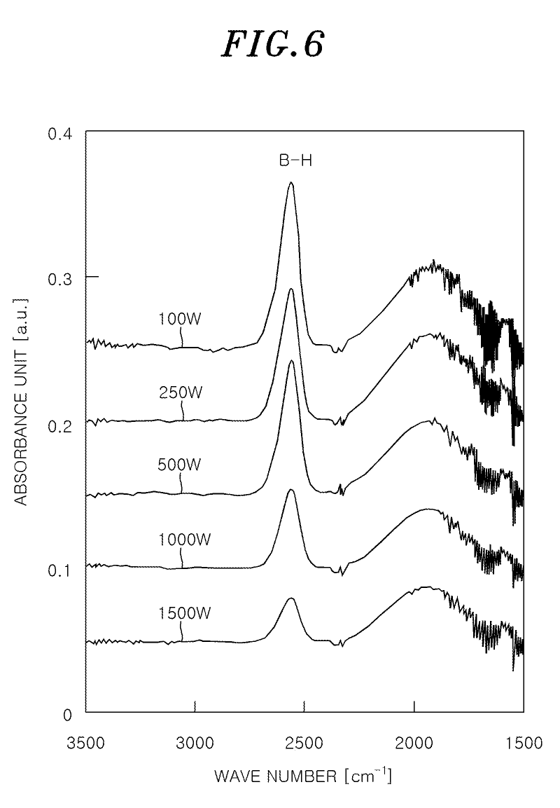

In the case of dissociating B₂H₆ as a boron source material in plasma, a large amount of radicals containing hydrogen such as BH₃, BH₂, or the like that have a small binding energy are generated when the electron temperature of the plasma is low. On the other hand, a large amount of ions such as B⁺, B⁺, or the like are generated when the electron temperature of the plasma is high. FIG. 6 shows the result of an FT-IR measurement of the boron film that is formed while varying the RF power for plasma generation. As can be seen from FIG. 6, the peak of the B—H bond becomes higher as the RF power for plasma generation is lowered. In other words, as the RF power for plasma generation is lowered, the electron temperature of the plasma becomes lower and the amount of hydrogen in the film is increased, which results in an increase in the number of B—H bonds. Since a film containing a large number of B—H bonds is H-terminated, the film structure is relaxed and film stress is reduced.

Further, by lowering the RF power for plasma generation, the flatness of the film can be improved. Specifically, when the RF power is 500 W or less, small surface roughness RMS of about 1 nm is obtained even when the boron-based film has a large film thickness of about 1 μm. Further, when the RF power is 100 W or less, a further improved surface roughness RMS of about 0.5 nm can be obtained. FIG. 7 is a graph showing a relationship between the film thickness and the surface roughness RMS of the boron film that was formed by setting the RF power for plasma generation to 1000 W and 100 W. As shown in FIG. 7, when the RF power is 1000 W, surface roughness RMS of about 2 nm is obtained when the film thickness is 1000 nm (1 μm). In contrast, when the RF power is 100 W, the surface roughness RMS is a very small value of about 0.5 nm, even when the film thickness is 1 μm. Specifically, high surface roughness RMS is maintained since the surface roughness is about 0.6 nm when the film thickness is 1.2 μm. Although it is not shown, when the RF power is 500 W, which is between 1000 W and 100 W, it is expected that the surface roughness RMS of about 1 nm may be obtained when the film thickness is about 1 μm.

From the above, it was found that as the RF power for plasma generation is lowered, the film stress is reduced while the flatness of the film is improved.

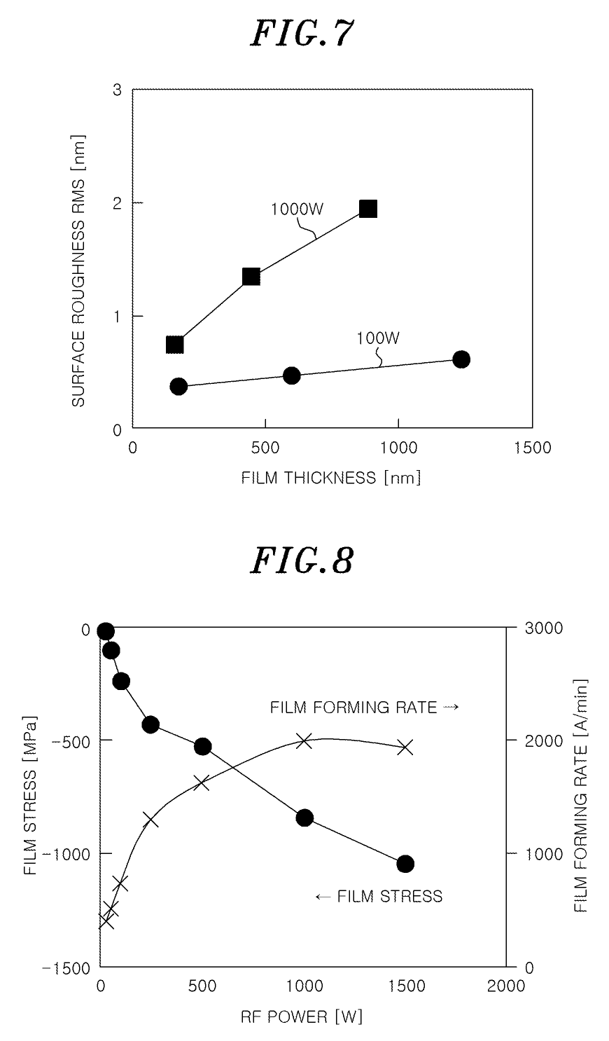

FIG. 8 is a graph showing a relationship between the RF power for plasma generation, the film stress, and the film forming rate. As shown in FIG. 8, while the film forming rate and the film stress are also reduced when the RF power is reduced to 500 W or less, and further to 100 W or less, they are still at practically acceptable levels.

The film stress of the boron-based film changes depending on the pressure or the Ar gas concentration in an inert gas. Generally, in plasma processing, the electron temperature of the plasma becomes lower as the pressure becomes higher or the Ar/He ratio of an inert gas becomes higher. As previously described, when the electron temperature is low, the number of B—H bonds in the film increases and, thus, the film structure is relaxed and the film stress is reduced. Accordingly, the film stress is reduced as the pressure becomes higher or the Ar/He ratio of the inert gas becomes higher. Therefore, the film stress of the boron-based film can also be adjusted by the pressure or the Ar gas concentration in the inert gas.

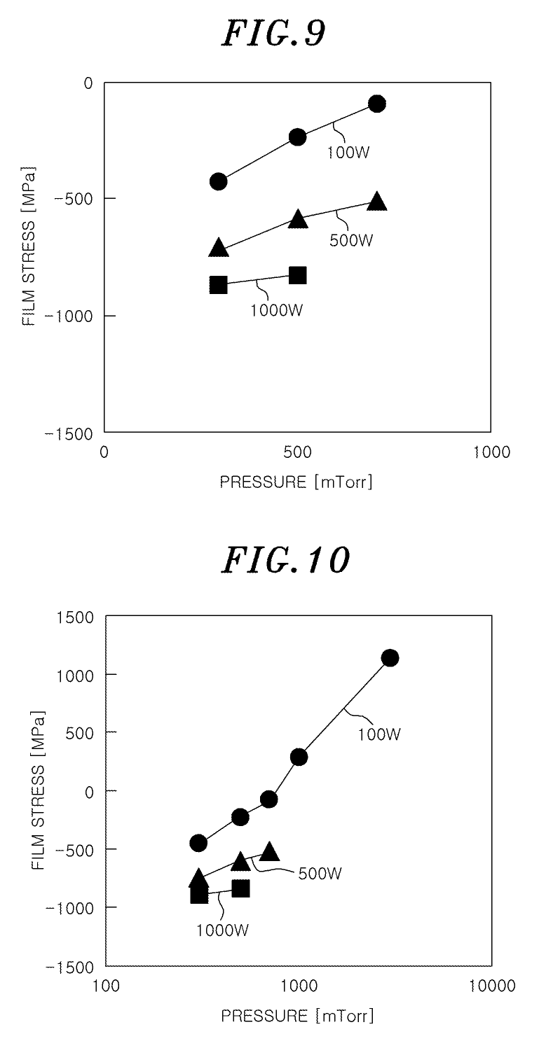

FIG. 9 is a graph showing a relationship between the pressure in the chamber and the film stress in the case of setting the RF power for plasma generation to 100 W, 500 W, and 1000 W. FIG. 10 is a graph showing the relationship shown in FIG. 9 to which a plot of a high-pressure side at 100 W is added while the pressure on the horizontal axis of FIG. 9 is converted to logarithmic scale.

Other processing conditions are as follows:

temperature: 300° C.,

B₂H₆ gas flow rate (B₂H₆ concentration: 15 vol % in He gas): 200 sccm (B₂H₆ gas (net amount): 30 sccm, He gas: 170 sccm),

Ar gas flow rate: 100 sccm,

He gas flow rate: 100 sccm, and

gap between electrodes: 20 mm.

As shown in FIGS. 9 and 10, the film stress is reduced as the pressure during film formation becomes higher. Further, as shown in FIG. 10, when the pressure is 1 Torr (133.3 Pa) or more, the film stress becomes positive and tensile stress is generated. From this, the pressure in the chamber may be preferably in a range from 300 mTorr (40 Pa) to 3 Torr (400 Pa), and more preferably in a range from 500 mTorr (66.7 Pa) to 1 Torr (133.3 Pa).

FIG. 11 is a graph showing a relationship between Ar gas dilution ratio (%) and the film stress in the case of setting the RF power for plasma generation to 100 W, 500 W, and 1000 W. The Ar gas dilution ratio (%) is a ratio of the Ar gas flow rate to the total flow rate of the processing gas (i.e., 400 sccm). The Ar gas flow rate is set to be in a range of 0 sccm to 200 sccm. Other processing conditions are as follows:

temperature: 300° C.,

B₂H₆ gas flow rate (B₂H₆ concentration: 15 vol % in He gas): 200 sccm (B₂H₆ gas (net amount): 30 sccm, He gas: 170 sccm),

pressure: 500 mTorr, and

gap between electrodes: 20 mm.

As shown in FIG. 11, the film stress is reduced as the Ar gas dilution ratio becomes higher.

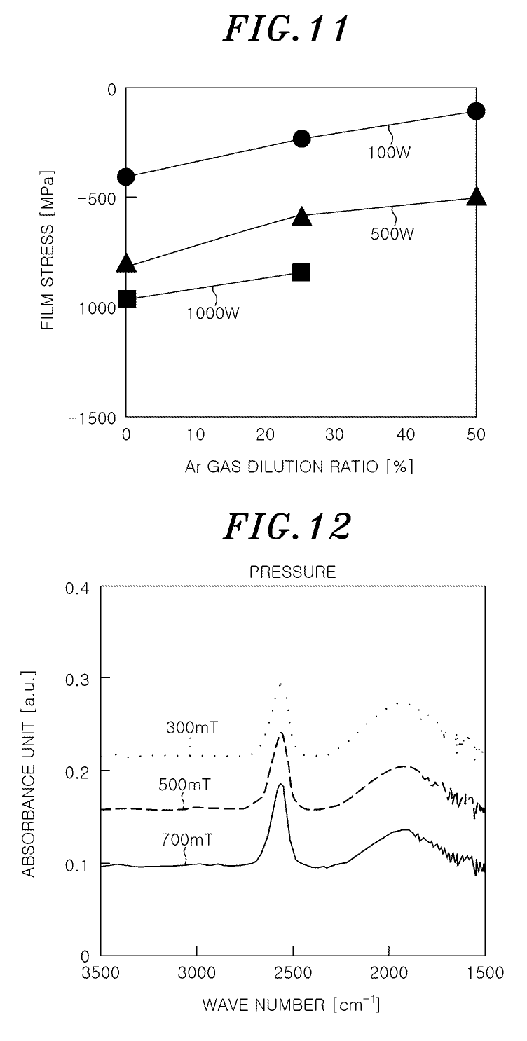

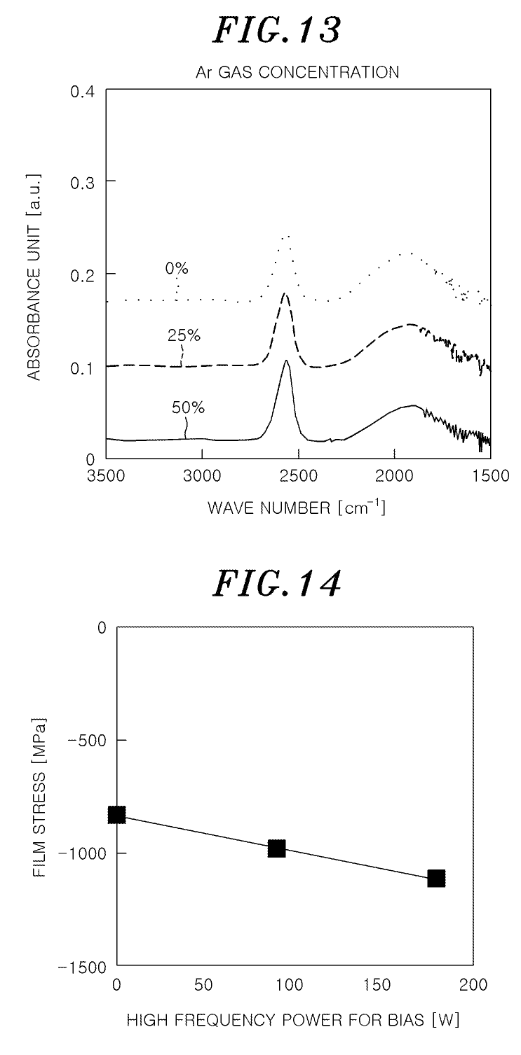

FIGS. 12 and 13 show the results of the FT-IR measurement of the boron film in the case of varying the pressure and the Ar gas dilution ratio, respectively. FIGS. 12 and 13 show that the B—H peak becomes higher as the pressure becomes higher and the Ar gas dilution ratio (the ratio of the Ar gas flow rate to the total flow rate of the processing gas) becomes higher.

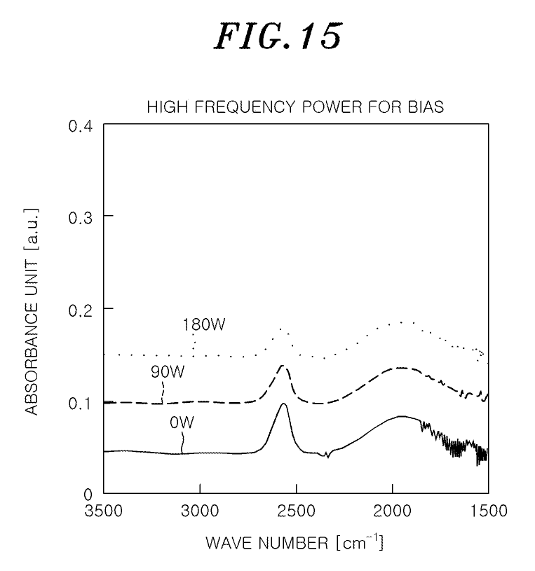

The film stress of the boron film can also be changed by the second high frequency power of the bias voltage application (high frequency power for bias). FIG. 14 is a graph showing a relationship between the high frequency power for bias and the film stress.

Other conditions at this time are as follows:

RF power for plasma generation: 500 W,

temperature: 300° C.,

pressure: 500 mTorr,

B₂H₆ gas flow rate (B₂H₆ concentration: 15 vol % in He gas): 200 sccm (B₂H₆ gas (net amount): 30 sccm, He gas: 170 sccm),

Ar gas flow rate: 100 sccm,

He gas flow rate: 100 sccm, and

gap between electrodes: 20 mm.

As shown in FIG. 14, the film stress is increased as the ion attraction in the plasma is increased by increasing the high frequency power for bias. Therefore, it is preferable not to apply the high frequency power for bias in order to reduce the film stress.

FIG. 15 shows a result of the FT-IR measurement of the boron film in the case of varying the high frequency power for bias. As shown in FIG. 15, as the high frequency power for bias is increased, the B—H peak becomes lower, the number of B—H bonds in the film is decreased, and the film stress is increased.

Considering that the film stress is increased by attracting ions in the plasma by the high frequency power for bias, it is expected that the film stress can be adjusted by controlling the action of the ions in the plasma to the wafer by controlling the impedance of the mounting table serving as the lower electrode. In other words, the film stress can be further reduced by adjusting the impedance of the mounting table serving as the lower electrode such that the ions in the plasma are repelled from the wafer on the mounting table.

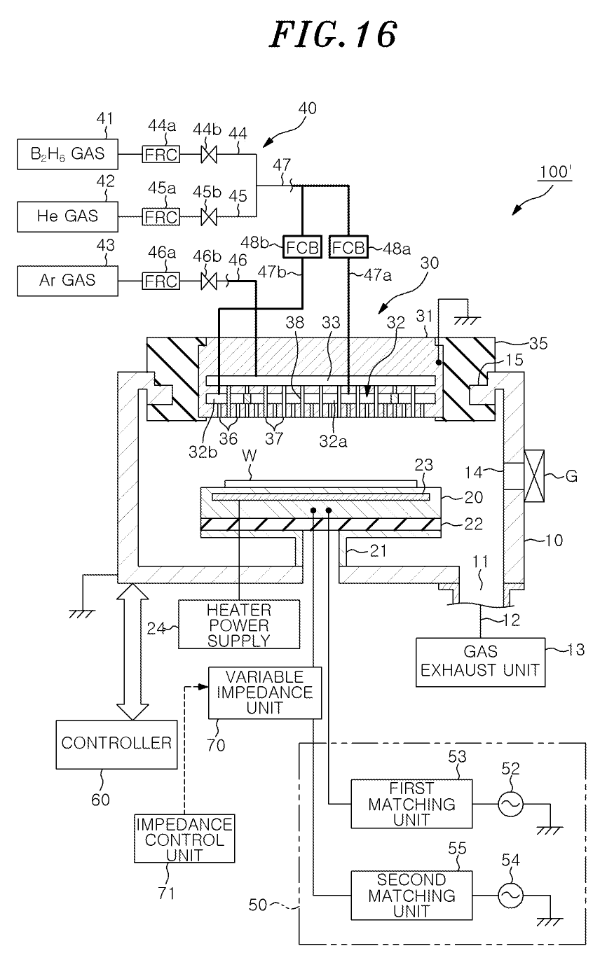

As for a mechanism for controlling the impedance of the lower electrode, there is one described in Japanese Patent Application Publication No. 2004-96066. FIG. 16 is a cross-sectional view showing an example of a film forming apparatus including such an impedance control mechanism. A film forming apparatus 100′ of FIG. 16 is configured by additionally providing a variable impedance unit 70 and an impedance control unit 71 in a power supply line of the second high frequency power supply 54 for bias voltage application in the film forming apparatus 100 of FIG. 1. The variable impedance unit 70 is configured to vary an impedance seen from the gas shower head 30 serving as the upper electrode. The impedance control unit 71 is configured to control an impedance of the variable impedance unit 70. The variable impedance unit 70 includes, e.g., a variable capacitor and a fixed coil provided in series in the power supply line of the second high frequency power supply 54. The impedance control unit 71 controls the impedance of the variable impedance unit 70 such that ions are repelled from the mounting table 20 serving as the lower electrode, thereby reducing the film stress of the boron film.

As described above, in accordance with the present embodiment, when a boron-based film (boron film) is formed by the capacitively-coupled plasma CVD, the film stress is adjusted by adjusting the RF power for plasma generation. Specifically, the film stress of the boron-based film (boron film) is reduced by lowering the RF power to 500 W or less, and further to 100 W or less, which are seldom used conventionally. Accordingly, it is possible to obtain a boron-based film (boron film) having a small film stress and further suitable for hard mask material while maintaining the characteristic that the etching selectivity is higher than that of a-C or a-Si, which have been conventionally used as hard mask material. Further, the surface roughness of the film can be reduced by lowering the RF power. In accordance with the present embodiment, a boron-based film (boron film) having excellent characteristics can be obtained.

Further, the film stress may be adjusted by other process parameters such as the pressure in the chamber during film formation, the Ar gas concentration (Ar flow rate/total flow rate of processing gas), the high frequency power for bias, and the like. The film stress can be optimized by controlling these parameters.

<Other Applications>

While the embodiments have been described above, the embodiments described above are considered to be illustrative in all aspects and not restrictive. The above-described embodiments may be omitted, replaced, or changed variously without departing from the scope and the gist of the following claims.

For example, in the above embodiments, a boron film is mainly described. However, a boron-based film containing boron and other additives that are intentionally added, e.g., a boron-rich BN film or a boron-rich BC film, may be used.

The film forming apparatus described in the above embodiments is merely an example, and it is preferable to use a capacitively coupled plasma CVD apparatus, but it is not limited thereto. For example, various film forming apparatuses in which a high frequency power for plasma generation is applied to an upper electrode may be used.

While the present disclosure has been shown and described with respect to the embodiments, it will be understood by those skilled in the art that various changes and modifications may be made without departing from the scope of the present disclosure as defined in the following claims

1. A boron-based film forming method for forming a boron-based film mainly containing boron on a substrate, comprising:
loading a substrate into a chamber of a film forming apparatus for forming the boron-based film by plasma CVD using capacitively-coupled plasma;
supplying a processing gas containing a boron-containing gas into the chamber;
applying a high frequency power for generating the capacitively-coupled plasma; and
forming the boron-based film on the substrate by generating a plasma of the processing gas by the high frequency power,
wherein a film stress of the boron-based film is adjusted by the high frequency power in said applying.

2. The boron-based film forming method of claim 1, wherein, in said applying, the high frequency power is 500 W or less.

3. The boron-based film forming method of claim 2, wherein, in said applying, the high frequency power is 100 W or less.

4. The boron-based film forming method of claim 1, wherein the film stress of the boron-based film is adjusted by a pressure in the chamber in said forming.

5. The boron-based film forming method of claim 4, wherein the pressure in the chamber is within a range from 300 mTorr (40 Pa) to 3 Torr (400 Pa).

6. The boron-based film forming method of claim 5, wherein the pressure in the chamber is within a range from 500 mTorr (66.7 Pa) to 1 Ton (133.3 Pa).

7. The boron-based film forming method of claim 1, wherein the processing gas contains a boron-containing gas and a rare gas.

8. The boron-based film forming method of claim 7, wherein the rare gas includes Ar gas and/or He gas, and the film stress of the boron-based film is adjusted by a ratio of the Ar gas and the He gas.

9. The boron-based film forming method of claim 1, wherein, in said forming, the film stress of the boron-based film is adjusted by controlling attraction of ions in the plasma to a mounting table, on which the substrate is mounted, by a high frequency power for bias voltage application applied to the mounting table.

10. The boron-based film forming method of claim 1, wherein, in said forming, the film stress of the boron-based film is adjusted by controlling action of ions in the plasma to the substrate mounted on a mounting table by an impedance of the mounting table.

11. The boron-based film forming method of claim 10, wherein, in said forming, the film stress of the boron-based film is adjusted by controlling the impedance of the mounting table on which the substrate is mounted such that ions in the plasma are repelled from the substrate on the mounting table.

12. The boron-based film forming method of claim 1, wherein the boron-based film is a boron film containing boron and inevitable impurities.

13. The boron-based film forming method of claim 1, wherein B₂H₆ gas is used as the boron-containing gas.

14. A boron-based film forming apparatus for forming a boron-based film mainly containing boron on a substrate, comprising:
a chamber accommodating a substrate;
a lower electrode serving as a mounting table configured to support the substrate in the chamber,
an upper electrode disposed to face the mounting table;
a gas supply mechanism configured to supply a processing gas containing a boron-containing gas into the chamber;
a high frequency power supply configured to generate a high frequency electric field between the lower electrode and the upper electrode; and
a controller configured to adjust a film stress of the boron-based film by controlling a high frequency power from the high frequency power supply,
wherein the boron-based film is formed by plasma of the processing gas that is generated by the high frequency electric field between the lower electrode and the upper electrode.

15. The boron-based film forming apparatus of claim 14, wherein the controller controls the high frequency power from the high frequency power supply to 500 W or less.

16. The boron-based film forming apparatus of claim 15, wherein the controller controls the high frequency power from the high frequency power supply to 100 W or less.

17. The boron-based film forming apparatus of claim 14, wherein the controller adjusts the film stress of the boron-based film by controlling a pressure in the chamber.

18. The boron-based film forming apparatus of claim 14, wherein the gas supply mechanism supplies B₂H₆ gas as the boron-containing gas.

19. The boron-based film forming apparatus of claim 14, wherein the gas supply mechanism supplies the boron-containing gas and Ar gas and/or He gas as a rare gas, and the controller adjusts the film stress of the boron-based film by controlling a ratio of the Ar gas and the He gas.

20. The boron-based film forming apparatus of claim 14, further comprising:
a high frequency power supply for bias voltage application which is configured to apply a high frequency power to the mounting table to apply a bias voltage to the substrate on the mounting table,
wherein the controller adjusts the film stress of the boron-based film by controlling attraction of ions in the plasma to the mounting table by the bias voltage.

21. The film forming apparatus of claim 14, further comprising:
an impedance control mechanism configured to adjust an impedance of the mounting table,
wherein the controller adjusts the film stress of the boron-based film by controlling the impedence of the mounting table to control action of ions in the plasma to the substrate on the mounting table.

22. The boron-based film forming method of claim 1, wherein a temperature of a mounting table, on which the substrate is mounted, is set to be in a range from 60 to 500° C.

23. The boron-based film forming method of claim 4, wherein a temperature of a mounting table, on which the substrate is mounted, is set to be in a range from 60 to 500° C.

24. The boron-based film forming method of claim 7, wherein a temperature of a mounting table, on which the substrate is mounted, is set to be in a range from 60 to 500° C.

25. The boron-based film forming apparatus of claim 14, wherein a temperature of the mounting table is set to be in a range from 60 to 500° C.

26. The boron-based film forming apparatus of claim 17, wherein a temperature of the mounting table is set to be in a range from 60 to 500° C.

27. The boron-based film forming apparatus of claim 19, wherein a temperature of the mounting table is set to be in a range from 60 to 500° C.

28. The boron-based film forming apparatus of claim 20, wherein a temperature of the mounting table is set to be in a range from 60 to 500° C.

29. The boron-based film forming apparatus of claim 21, wherein a temperature of the mounting table is set to be in a range from 60 to 500° C.
